(19) United States
(12) Patent Application Publication
(10) Pub. No.: US 2011/0155422 A1
(43) Pub. Date: Jun. 30, 2011

(54) WIRE INSULATING TERMINAL AND CIRCUIT BOARD MODULE EMPLOYING SAME

(75) Inventor: Hung-Chuan Chen, Taoyuan Hsien (TW)

(73) Assignee: DELTA ELECTRONICS, INC., Taoyuan Hsien (TW)

(21) Appl. No.: 12/974,839

(22) Filed: Dec. 21, 2010

(30) Foreign Application Priority Data
Dec. 28, 2009 (TW) 098145384

(51) Int. Cl. H05K 1/00; H02G 15/00

(52) U.S. Cl. 174/250; 174/70 R

(57) ABSTRACT

There is disclosed a wire insulating terminal which includes a wire insulating terminal member having an inner insulating wall and an outer insulating wall, and at least one conducting wire having a bared wire end. The inner insulating wall forms a perforation channel with a first opening and a second opening which are respectively disposed on the two opposite ends of the perforation channel to accommodate the at least one conducting wire with the bared wire end partially protruding out from the second opening. The outer insulating wall includes a first connecting member and a second connecting member which are configured to be corresponsive to and engageable with each other.

### FIELD OF THE INVENTION

The present invention relates to a wire insulating terminal, and more particularly to an improved wire insulating terminal structure with a modular wire insulating terminal member and a circuit board module employing a plurality of such improved wire insulating terminals.

### BACKGROUND OF THE INVENTION

It is well known to the industry that conducting wires play a great role in conveying electrical power among various electronic components or between those and a circuit board. The design and fabrication having the wires involved within an electronic device always comes with certain safety issues. The arrangements for wires, and more particular for dealing with the end of wire conductors or conducting cores, become severely critical especially since the latest design requirements of, such as higher safety, high-density and economic fabrication, are all pressing harder than ever.

There have been developed various solutions. In a conventional way, a wire terminal as illustrated in FIG. 1 is formed by joining one end of a plurality of conducting wires 12 into a wire barrel 11 as illustrated in FIG. 2. The wire barrel 11 is made of metal comprising three pairs of metal clips 111. Each of the metal clips 111 is in the shape of crimp with high flexibility in clamping an inserted object. Those metal clips 111 are integrally connected with each other and are configured to substantially form a perforation channel 22. The conducting wires 12 are thus able to be embedded into the wire barrel 11 through the perforation channel 22. Giving certain force by tools or fixtures in assembly, the metal clips 111 are pressed against the conducting wires 12 to respectively clamp a wire insulation portion 121 and a bared wire end 122 of the conducting wires 12 and can further secure the conducting wires 12 to the wire barrel 11. The illustrated wire terminal is capable of being connected to a component within an electronic device, such as a through hole on a circuit board (not shown). The foregoing solution seems to be simple and safe. But several disadvantages emerge.

The conductive areas of the conventional wire terminal can be freely extended to all over the terminal, even to the metal clips 111 clamping the wire insulation portion 121. This would constitute a major threat to the components nearby forming an electric safety issue thereof. The metal clips 111 on the wire barrel 11 are actually extended in the shape of strip, and requires to be properly pressed downward in manufacturing. It is understood that, after assembly, some conductors of the conducting wires 12 may protrude out from the gaps between the strips formed by the metal clips 111, or they are out due to a loose or failure clamping from the metal clips 111. In some occasions, some of the metal clips are improperly extended outwardly to increase the conductive risk. It is quite common to find these failures in manufacturing resulting from certain manufacturing processes, such as re-work, inspection, or assembly etc.

In addition, the illustrated solution is hard to meet the rigid economic fabrication requirements due to these potential failures. They would require extra efforts to attend in not only the manufacturing phase but also the maintenance after sale.

Under the prevailing design requirements described above, a wire terminal which is capable of meeting the demands for higher electrical safety, more flexibility in design and simpler construction is apparently in need.

### SUMMARY OF THE INVENTION

It is an object of the present invention to provide a wire insulating terminal having a wire insulating terminal member and a circuit board module employing a plurality of such improved wire insulating terminals, in which the wire insulating terminal member forming the wire insulating terminal or the circuit board module is constructed on an insulation basis to substantially isolate the conductor of a conducting wire from the components nearby so as to improve the electrical safety thereof.

It is another object of the present invention to provide a wire insulating terminal having a wire insulating terminal member, in which the wire insulating terminal member is modular and of simple construction to form the wire insulating terminal or a circuit board module so as to achieve the economic fabrication.

It is another object of the present invention to provide a wire insulating terminal having a wire insulating terminal member, in which the wire insulating terminal member that obtains more room for components deployment may serve the need to meet the design flexibility under various high-density requirements.

In accordance with an aspect of the present invention, there is provided a wire insulating terminal comprising a wire insulating terminal member having an inner insulating wall and an outer insulating wall, and at least one conducting wire having a bared wire end. The inner insulating wall forms a perforation channel with a first opening and a second opening which are respectively disposed on two opposite ends of the perforation channel to accommodate the at least one conducting wire with the bared wire end partially protruding out from the second opening. Preferably, the first opening is greater than the second opening. The outer insulating wall includes a first connecting member and a second connecting member which are configured to be corresponsive to and engageable with each other.

In an embodiment, the at least one conducting wire includes a wire insulation portion. The perforation channel includes a third opening disposed between the first opening and the second opening with an opening measurement between the same and forming a first tube between the first opening and the third opening, and a second tube between the second opening and the third opening.

In an embodiment, the wire insulation portion is substantially embedded in the first tube. The inner insulating wall includes a clamping member protruding in the first tube for clamping the wire insulation portion. The clamping member is a projecting flange or a plurality of protrusions.

In an embodiment, the outer insulating wall includes four outer walls substantially horizontal to a longitudinal axis of the perforation channel which are connected with each other. Each of the four outer walls includes either the first connecting member or the second connecting member. The first connecting member is a projecting rib and the second connecting member is a slot corresponsive and complementary to the projecting rib. The at least one conducting wire is an output wire of a power supply.

In accordance with another aspect of the present invention, there is provided a circuit board module comprising a circuit board having a plurality of through holes, and a plurality of the wire insulating terminals having modular wire insulating terminal members as described above. The first connecting member of one the modular wire insulating terminal member is engaged with the second connecting member of another connected one. The wire insulating terminals are connected with each other and the bared wired ends are connected to the through holes, so as to form the circuit board module.

It is easily to be understood that the wire insulating terminal with the wire insulating member according to the present invention is modular and may increase higher electrical safety and save labor and time in fabricating due to the modular and simpler construction. It also comes with an advantage of allowing higher flexibility in design arrangements.

These and various other features and advantages which characterize the present invention are particularly underlined in the claims annexed hereto and form a part hereof. As such, the present invention will become best understood through the following detailed descriptions with reference to the accompanying drawings, in which:

### BRIEF DESCRIPTION OF THE DRAWINGS

FIG. 1 illustrates an assembled view schematically showing a conventional wire terminal;

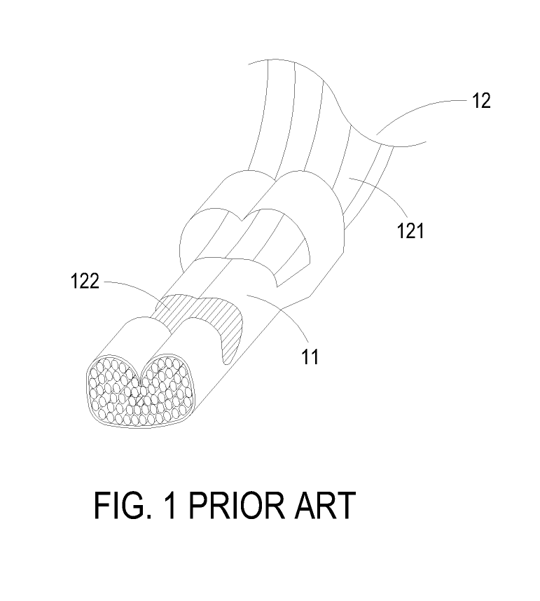

FIG. 2 is a schematic view of a conventional crimping terminal as in FIG. 1;

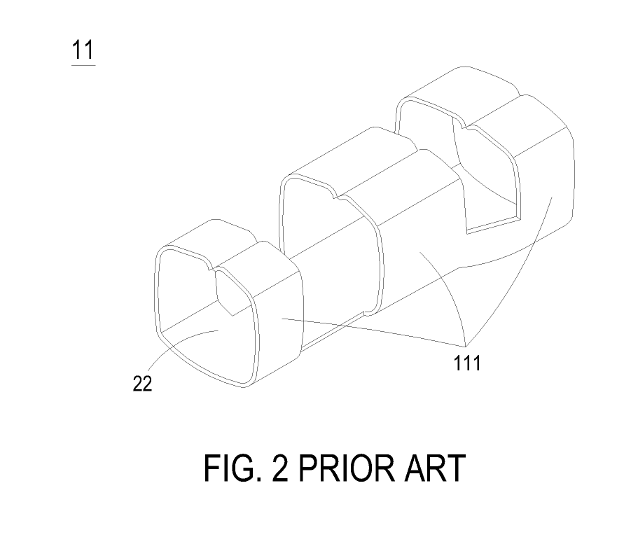

FIG. 3 illustrates a perspective view schematically showing a wire insulating terminal member according to one embodiment of the present invention;

FIG. 4 illustrates an assembled view schematically showing a wire insulating terminal according to one embodiment of the present invention; and

FIG. 5 is an exploded view schematically showing a circuit board module according to one embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

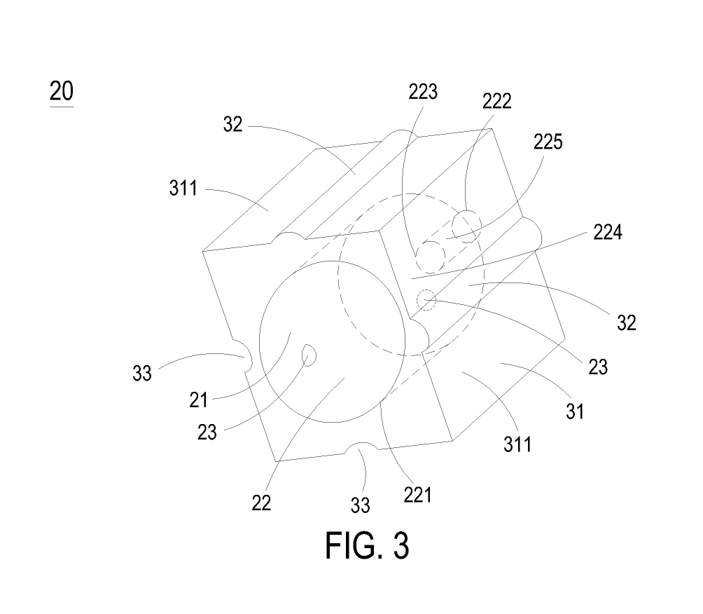

FIG. 3 schematically illustrates a wire insulating terminal member according to one embodiment of the present invention. The wire insulating terminal member 20 includes an inner insulating wall 21 and an outer insulating wall 31. The inner insulating wall 21 forms a perforation channel 22 with a first opening 221 and a second opening 222 which are respectively disposed on the two opposite ends of the perforation channel 22 so as to accommodate at least one conducting wire (not shown). The first opening 221 of the perforation channel 22 is configured for receiving the conducting wire into the perforation channel 22 when the second opening 222 is for being an outlet of the conducting wire that has been received. In this embodiment, the first opening 221 is greater than the second opening 222.

As shown in FIG. 3, the perforation channel 22 can include a third opening 223 disposed between the first opening 221 and the second opening 222 with an opening measurement between the same. The third opening 223 further defines and forms a first tube 224 between the first opening 221 and the third opening 223, and a second tube 225 between the second opening 222 and the third opening 223. The inner insulating wall 21 can include a clamping member 23 protruding in the first tube 224 for clamping the conducting wire within the perforation channel 22. In this embodiment, the clamping member 23 is a pair of protrusions projecting oppositely and corresponsively. But it is well known to those skilled in the art that there are many similar arrangements in clamping and may be used here. For example, it could be a flange or a plurality of protrusions irregularly arranged on the inner wall 21 within the first tube 224.

The outer insulating wall 31 includes a first connecting member 32 and a second connecting member 33 which are configured to be corresponsive to and engageable with each other. As illustrated in FIG. 3, the outer insulating wall 31 can further include four outer walls 311 which are each substantially horizontal to the longitudinal axis of the perforation channel 22 and are connected with each other. In this embodiment, the first connecting member 32 is a projecting rib when the second connecting member 33 is a slot, and either of them is disposed on each of the four outer walls 311. The slot is corresponsive and complementary to the projecting rib. Of course, other similar ways for achieving the engageable result are also known in the art and may be used here.

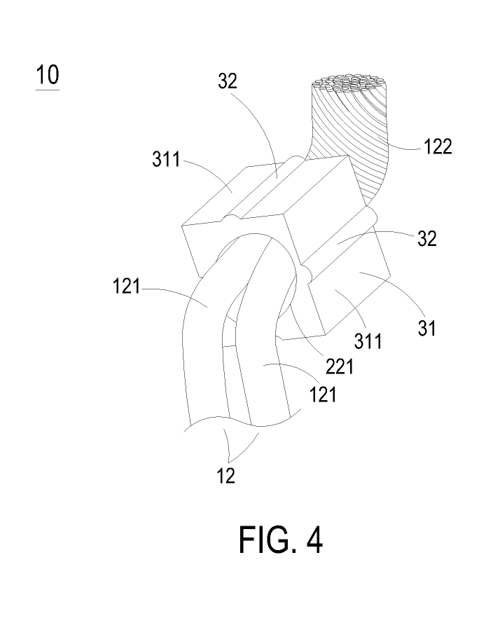

Referring to FIG. 4, there illustrates an assembled view of a wire insulating terminal 10 according to one embodiment of the present invention which includes the wire insulating terminal member 20 as described above and at least one conducting wire 12. The conducting wire 12 includes a wire insulation portion 121 and a bared wire end 122. In assembly, the wire insulation portion 121 is substantially embedded in the first tube 224 of the perforation channel 22, and is clamped by the clamping member 23. The bared wire end 122 is partially protruding out from the second opening 222. The perforation channel 22 including the first tube 224 and the second tube 225 serves as a room for accommodating the conducting wire 12 including the insulation portion 121 and the bared wire end 122. The measurement of each part of the room may vary according to the need as the case may require. The illustrated wire insulating terminal of the present invention can be used with various wires within an electronic device, such as an output conducting wire of a switching power supply.

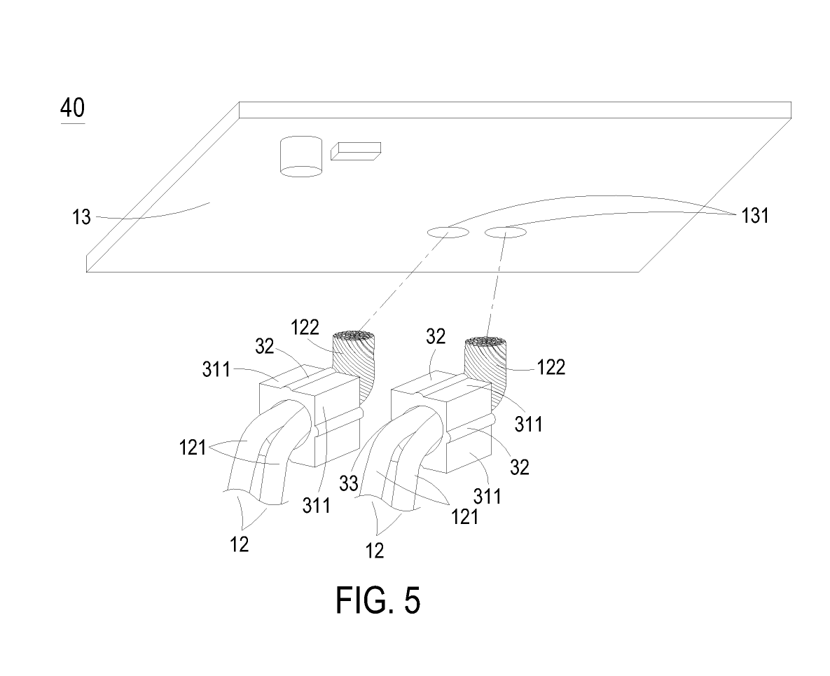

Owning to the structure of each wire insulating terminal 10 being modular as described above, a circuit board module 40 is also available as shown in FIG. 5 according to one embodiment of the present invention. As illustrated, a plurality of the wire insulating terminals 10 are available to be connected to a plurality of through holes 131 disposed on a circuit board 13. The first connecting member 32 of one modular wire insulating terminal member 20 is engaged with the second connecting member 33 of another connected one. The conducting wires 12 of each wire insulating terminal 10 are embedded in the perforation channel 22 with their bared wire ends 122 partially protruding out from the second opening 222 of the perforation channel 22 and being inserted into one of a plurality of through holes 131 on the circuit board 13. In some cases, a certain portion of the inner wall of the through holes 131 can be conductive, and further soldering process may be required in connecting the bared wire end 122 to the through hole 131.

In this embodiment, each of the through holes 131 is available to provide for example 12V output power conveyed by the conducting wires 12 of the wire insulating terminal 10 from a switching power supply (not shown).

The invention as disclosed and presented herein are thus advantageous to resolve the disadvantages in the prior art.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A wire insulating terminal comprising:
a wire insulating terminal member having an inner insulating wall forming a perforation channel with a first opening and a second opening respectively disposed on the two opposite ends of said perforation channel, wherein said first opening is greater than said second opening, and having an outer insulating wall including a first connecting member and a second connecting member which are configured to be corresponsive to and engageable with each other; and
at least one conducting wire embedded in said perforation channel having a bared wire end partially protruding out from said second opening.

2. The wire insulating terminal according to claim 1, wherein said at least one conducting wire comprises a wire insulation portion.

3. The wire insulating terminal according to claim 2, wherein said perforation channel comprises a third opening disposed between said first opening and said second opening with an opening measurement between the same and forming a first tube between said first opening and said third opening, and a second tube between said second opening and said third opening.

4. The wire insulating terminal according to claim 3, wherein said wire insulation portion is substantially embedded in said first tube.

5. The wire insulating terminal according to claim 4, wherein said inner insulating wall comprises a clamping member protruding in said first tube for clamping said wire insulation portion.

6. The wire insulating terminal according to claim 5, wherein said clamping member is a projecting flange or a plurality of protrusions.

7. The wire insulating terminal according to claim 1, wherein said outer insulating wall comprises four outer walls substantially horizontal to a longitudinal axis of said perforation channel which are connected with each other.

8. The wire insulating terminal according to claim 7, wherein each of said four outer walls comprises either said first connecting member or said second connecting member.

9. The wire insulating terminal according to claim 1, wherein said first connecting member is a projecting rib and said second connecting member is a slot corresponsive and complementary to said projecting rib.

10. The wire insulating terminal according to claim 1, wherein said at least one conducting wire is an output wire of a power supply.

11. A circuit board module comprising:
a circuit board having a plurality of through holes;
a plurality of wire insulating terminals connected with each other and each wire insulating terminal having a modular wire insulating terminal member and at least one conducting wire; said modular wire insulating terminal member having an inner insulating wall forming a perforation channel with a first opening and a second opening respectively disposed on two opposite ends of said perforation channel, wherein said first opening is greater than said second opening, and having an outer insulating wall including a first connecting member and a second connecting member which are configured to be corresponsive to and engageable with each other, said at least one conducting wire embedded in said perforation channel having a bared wire end partially protruding out from said second opening and connected to one of said through holes; and
wherein said first connecting member of one said modular wire insulating terminal member is engaged with said second connecting member of another connected one.

12. The circuit board module according to claim 11, wherein said at least one conducting wire comprises a wire insulation portion.

13. The circuit board module according to claim 12, wherein said perforation channel comprises a third opening disposed between said first opening and said second opening with an opening measurement between the same and forming a first tube between said first opening and said third opening, and a second tube between said second opening and said third opening.

14. The circuit board module according to claim 13, wherein said wire insulation portion is substantially embedded in said first tube.

15. The circuit board module according to claim 14, wherein said inner insulating wall comprises a clamping member protruding in said first tube for clamping said wire insulation portion.

16. The circuit board module according to claim 15, wherein said clamping member is a projecting flange or a plurality of protrusions.

17. The circuit board module according to claim 11, wherein said outer insulating wall comprises four outer walls substantially horizontal to a longitudinal axis of said perforation channel which are connected with each other.

18. The circuit board module according to claim 17, wherein each of said four outer walls comprises either said first connecting member or said second connecting member.

19. The circuit board module according to claim 11, wherein said first connecting member is a projecting rib and said second connecting member is a slot corresponsive and complementary to said projecting rib.

20. The circuit board module according to claim 11, wherein said circuit board is used for a switching power supply.
